(19) United States
(12) Patent Application Publication
(10) Pub. No.: US 2024/0333252 A1
(43) Pub. Date: Oct. 3, 2024

(54) SURFACE ACOUSTIC WAVE RESONATOR HAVING ELECTRODE STRUCTURE WITH IMPROVED PERFORMANCE AND MANUFACTURING METHOD THEREOF

(71) Applicant: WISOL CO., LTD., Osan-si (KR)

(72) Inventors: Hun Yong LEE, Osan-si (KR); Kang Ho KIM, Osan-si (KR); Sang Hoon MYEONG, Osan-si (KR); Min Hyeong LEE, Osan-si (KR)

(21) Appl. No.: 18/610,611

(22) Filed: Mar. 20, 2024

(30) Foreign Application Priority Data
Mar. 28, 2023 (KR) 10-2023-0040814

(51) Int. Cl. H03H 9/145; H03H 3/08; H03H 9/25

(52) U.S. Cl. CPC H03H 9/14541; H03H 3/08; H03H 9/25

(57) ABSTRACT

Provided are a SAW resonator having an electrode structure with improved performance and a method of manufacturing the same. The SAW resonator includes a piezoelectric substrate; and a plurality of IDT electrodes formed on the piezoelectric substrate, wherein each of the plurality of IDT electrodes includes: a seed layer stacked on a surface of the piezoelectric material; and a main electrode layer formed on the seed layer, and an amorphous layer is formed on a top surface of the piezoelectric substrate.

### BACKGROUND OF THE INVENTION

### Field of the Invention

The present invention relates to a Surface Acoustic Wave (SAW) resonator having an electrode structure with improved performance, and more specifically, to a SAW resonator that can improve electrical performance by improving crystallinity and orientation of an electrode when an electrode having a lattice structure different from that of a piezoelectric substrate is stacked on the piezoelectric substrate, and a method of manufacturing the same.

### Background of the Related Art

A Surface Acoustic Wave (SAW) refers to a wave that propagates along the surface of an elastic solid, and the surface acoustic wave propagates with energy concentrated near the surface, and corresponds to a mechanical wave. A surface acoustic wave device is an electromechanical device that utilizes the interaction between the surface acoustic wave and conduction electrons of a semiconductor, which uses surface acoustic waves transferred to the surface of a piezoelectric crystal. The surface acoustic wave device may have a very wide application area industrially such as sensors, oscillators, filters, and the like, can be miniaturized and lightweighted, and may have various advantages such as robustness, stability, sensitivity, low price, real-time performance, and the like.

In accordance with the trend of producing electronic components required to be miniaturized, a structure stacking two metals in an IDT electrode has been applied in a SAW resonator as shown in FIG. 1 of the prior art.

Referring to FIG. 1, the cross-sectional view of a plurality of IDT electrodes 50 is shown, and a SAW resonator 10 according to the prior art includes a plurality of IDT electrodes 50 formed on a substrate 1, in each of which a first metal layer 20 and a second metal layer 30 are sequentially stacked. The second metal layer 30 is the main electrode layer and may include aluminum (Al) or the like, and the first metal layer 20 may include a metal having a density higher than that of the second metal layer 30, such as tungsten (W), platinum (Pt), molybdenum (Mo), copper (Cu), or the like.

As the second metal layer 30 of low density is stacked on the first metal layer 20 of high density as the main electrode, acoustic velocity of the surface acoustic wave can be reduced, and therefore, there is an effect of contributing to miniaturization of the resonator 10. However, in the case of depositing the first metal layer 20 of high density through sputtering and forming the IDT electrodes 50 through etching, performance cannot be satisfied when the crystallinity and orientation of the deposited first metal layer 20 do not reach a predetermined level, and in addition, as the first metal layer 20 is unevenly etched in the process of etching the first metal layer 20 deposited in a form without crystallinity, residual materials of the first metal layer 20 remain on the piezoelectric substrate, and therefore, an unwanted spurious mode occurs, and a problem of lowering reliability and power durability may be generated.
(Patent Document 1) Korea Laid-opened Patent No. 10-2003-0057386

### SUMMARY OF THE INVENTION

Therefore, the present invention has been made in view of the above problems, and it is an object of the present invention to provide a SAW resonator including IDT electrodes of a multi-stacking structure, and a method of manufacturing the same, which can miniaturize a SAW filter, improve crystallinity and orientation of a plurality of metal layers constituting the IDT electrodes, and maintain etching quality.

The technical problems of the present invention are not limited to the technical problems mentioned above, and unmentioned other technical problems will be clearly understood by those skilled in the art from the following description.

A SAW resonator having an electrode structure with improved performance according to some embodiments of the present invention for accomplishing the above object comprises: a piezoelectric substrate; and a plurality of IDT electrodes formed on the piezoelectric substrate, wherein each of the plurality of IDT electrodes includes: a seed layer stacked on the surface of the piezoelectric substrate; and a main electrode layer formed on the seed layer, and an amorphous layer is formed on the top surface of the piezoelectric substrate.

In some embodiments of the present invention, at least one among the plurality of IDT electrodes may be a contact electrode, and the contact electrode may further include an ohmic contact layer formed on the main electrode layer.

In some embodiments of the present invention, the resonator may further comprise a wiring layer formed on the ohmic contact layer, being in contact with the contact electrode, and including a lower wiring layer, and the ohmic contact layer and the lower wiring layer form an ohmic contact.

In some embodiments of the present invention, the ohmic contact layer may include titanium, titanium nitride (TiN), titanium oxide (TiOx), and titanium-tungsten (TiW).

In some embodiments of the present invention, the main electrode layer may include a lower main electrode layer and an upper main electrode layer that are sequentially stacked.

In some embodiments of the present invention, the lower main electrode layer may include a metal having a density higher than that of the upper main electrode layer.

In some embodiments of the present invention, the lower main electrode layer may include at least any one among tungsten (W) and copper (Cu), and the upper main electrode layer may include aluminum (Al).

In some embodiments of the present invention, the piezoelectric substrate may include: a support substrate; an energy confinement layer formed on the support substrate; and a piezoelectric layer formed on the energy confinement layer, and the energy confinement layer includes a low acoustic velocity layer and/or a high acoustic velocity layer.

In some embodiments of the present invention, the seed layer may include at least any one among titanium, titanium nitride (TiN), titanium oxide (TiOx), titanium-tungsten (TiW), and chromium (Cr).

In some embodiments of the present invention, the resonator may further comprise an insulating layer between the plurality of IDT electrodes and the amorphous layer.

A method of manufacturing a SAW resonator having an improved electrode structure according to some embodiments of the present invention for accomplishing the above object comprises the steps of: preparing a piezoelectric substrate; forming an amorphous layer by performing surface treatment on the surface of the piezoelectric substrate by ion implantation or plasma treatment; forming a seed layer on the amorphous layer; forming a main electrode layer on the seed layer; and forming a plurality of IDT electrodes by etching the seed layer and the main electrode layer.

In some embodiments of the present invention, the method of manufacturing a SAW resonator may further comprise, before the step of forming a plurality of IDT electrodes, the step of forming an ohmic contact layer on the main electrode layer.

In some embodiments of the present invention, the method of manufacturing a SAW resonator may further comprise, after the step of forming a plurality of IDT electrodes, the step of forming a wiring layer on the ohmic contact layer to be in contact with a contact electrode that is one among the plurality of IDT electrodes, and the ohmic contact layer and the wiring layer may form an ohmic contact.

In some embodiments of the present invention, the method of manufacturing a SAW resonator may further comprise, before the step of forming a plurality of IDT electrodes, the step of forming an insulating layer between the seed layer and the amorphous layer.

In some embodiments of the present invention, the step of forming a main electrode layer may include the step of sequentially stacking a lower main electrode layer and an upper main electrode layer, and the lower main electrode layer may include a material having a density higher than that of the upper main electrode layer.

In some embodiments of the present invention, the lower main electrode layer may include at least any one among tungsten (W) and copper (Cu), and the upper main electrode layer may include aluminum (Al).

Details of the other embodiments are included in the detailed description and drawings.

According to a SAW resonator having an improved electrode structure and a method of manufacturing the same according to an embodiment of the present invention, an amorphous layer may be formed on the top surface of a piezoelectric substrate, and orientation and crystallinity of the main electrode layer can be improved through lattice alignment by a seed layer formed between the amorphous layer and the main electrode layer. The orientation and crystallinity of all main electrode layers are improved even in an IDT electrode of a multi-stacking structure for miniaturization, and in addition, an effect of improving the etching quality of the main electrode layer can be obtained by the seed layer. Therefore, miniaturization can be maintained while improving performance of the SAW resonator.

In addition, as the SAW resonator having an improved electrode structure according to an embodiment of the present invention additionally includes an ohmic contact layer on the IDT electrode, specifically on the main electrode layer, a state of ohmic contact rather than capacitive contact can be maintained when a wiring layer is formed on the IDT electrode thereafter.

In addition, when an insulating layer is formed between the piezoelectric substrate, on which the amorphous layer is formed, and the seed layer, the etching quality of the main electrode layer can be further improved without deteriorating orientation and crystallinity of the main electrode layer.

The effects of the present invention are not limited to the effects mentioned above, and unmentioned other effects will be clearly understood by those skilled in the art from the description of the claims.

### BRIEF DESCRIPTION OF THE DRAWINGS

FIG. 1 is a view showing a SAW resonator including a plurality of IDT electrodes according to the prior art.

FIGS. 2A and 2B are views showing a SAW resonator having an improved electrode structure according to an embodiment of the present invention.

FIG. 3 is a view for explaining the effect of a SAW resonator according to an embodiment of the present invention.

FIGS. 4A to 4C are graphs for explaining the effect of a SAW resonator according to an embodiment of the present invention.

FIG. 5 is a view showing a SAW resonator having an improved electrode structure according to another embodiment of the present invention.

FIG. 6 is a view showing a SAW resonator having an improved electrode structure according to still another embodiment of the present invention.

FIG. 7 is a view showing a SAW resonator having an improved electrode structure according to still another embodiment of the present invention.

FIGS. 8 and 9 are views for explaining the effect of the SAW resonator 400 according to the embodiment of FIG. 7.

FIG. 10 is a flowchart illustrating a method of manufacturing a SAW resonator having an improved electrode structure according to an embodiment of the present invention.

FIGS. 11 to 16 are intermediate views for explaining a method of manufacturing a SAW resonator having an improved electrode structure according to an embodiment of the present invention.

FIG. 17 is a flowchart illustrating a method of manufacturing a SAW resonator having an improved electrode structure according to another embodiment of the present invention.

FIGS. 18 and 19 are intermediate views for explaining a method of manufacturing a SAW resonator having an improved electrode structure according to another embodiment of the present invention.

### DETAILED DESCRIPTION OF THE PREFERRED EMBODIMENT

The advantages and features of the present invention and the method for achieving them will become clear by referring to the embodiments described below in detail together with the accompanying drawings. However, the present invention is not limited to the embodiments disclosed below and will be implemented in various different forms. These embodiments are provided only to make the disclosure of the present invention complete and to fully inform those skilled in the art of the present invention of the scope of the present invention, and the present invention is defined by the scope of the claims. Like reference numerals refer to like elements throughout the specification.

When one component is referred to as being “connected to” or “coupled to” another component, it includes both the cases of being directly connected or coupled to another components and cases of interposing other components in between. On the contrary, when one component is referred to as being “directly connected to” or “directly coupled to” another component, it indicates that no other component is intervening therebetween. “And/or” includes each of the mentioned items and all combinations of one or more of the items.

The terms used in this specification are to describe the embodiments and are not to limit the present invention. In this specification, singular forms also include plural forms unless specifically stated otherwise in the context. The terms “comprises” and/or “comprising” used in this specification means that the mentioned components, steps, operations, and/or elements do not exclude the presence or addition of one or more other components, steps, operations and/or elements.

Although first, second, and the like are used to describe various components, these components are of course not limited by these terms. These terms are used only to distinguish one component from the others. Therefore, it goes without saying that a first component mentioned below may also be a second component within the technical spirit of the present invention.

Unless defined otherwise, all the terms (including technical and scientific terms) used in this specification may be used as meanings that can be commonly understood by those skilled in the art. In addition, terms defined in commonly used dictionaries are not interpreted ideally or excessively unless clearly and specifically defined.

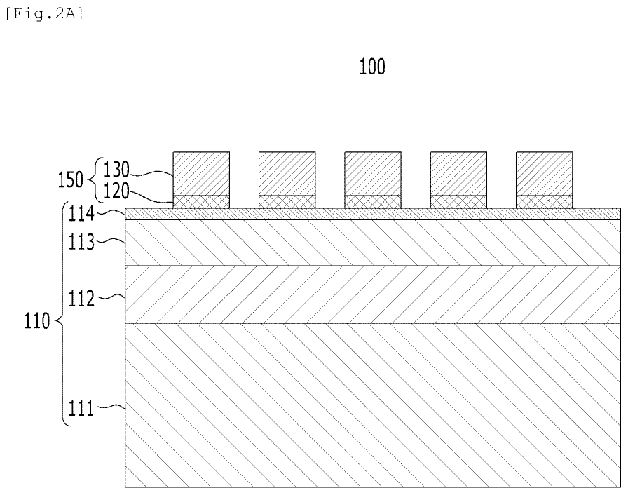

FIGS. 2A and 2B are cross-sectional views showing a SAW resonator having an improved electrode structure according to an embodiment of the present invention.

Referring to FIG. 2A, a SAW resonator 100 having an electrode structure with improved performance according to an embodiment of the present invention may include a plurality of IDT electrodes 150 formed on a piezoelectric substrate 110, each including a seed layer 120 and a main electrode layer 130.

The piezoelectric substrate 110 may be formed by sequentially stacking an energy confinement layer 112 and a piezoelectric layer 113 on a support substrate 111 that is at the bottom. The support substrate 111 may be formed as, for example, a semiconductor substrate of silicon, as well as a ceramic substrate, an insulating substrate, or the like.

The energy confinement layer 112 is a layer that transfers waves of an acoustic velocity lower or higher than that of elastic waves propagated by the piezoelectric layer 113, and may be configured to confine the elastic waves on the surface of a high acoustic velocity layer 112B as a low acoustic velocity layer 112A is stacked on the high acoustic velocity layer as shown in FIG. 2B for example, or may be configured of either the high acoustic velocity layer or the low acoustic velocity layer alone as shown in FIG. 2A. The high acoustic velocity layer constituting the energy confinement layer 112 may include at least one among the materials such as aluminum nitride, aluminum oxide, silicon nitride, silicon oxynitride, silicon, and the like, and the low acoustic velocity layer may be configured to include at least one among various known materials such as silicon oxide, glass, silicon oxynitride, and the like.

The piezoelectric layer 113 may include a piezoelectric element to generate elastic waves from a signal applied to the IDT electrode 150, and may include materials such as LiTaO₃ (LT), LiNbO₃ (LN), and the like.

An amorphous layer 114 may be formed on the surface of the piezoelectric layer 113 by performing ion implantation or plasma treatment on the surface. This is to prevent deposition quality of the IDT electrode 150 from being affected by inherent characteristics such as the lattice structure and angle unique to the piezoelectric substrate 110. That is, the amorphous layer 114 is intended to invalidate the inherent characteristics of the piezoelectric substrate 110, more specifically the piezoelectric layer 113, and it may be desirable to form the amorphous layer 114 not to be too thick on the top surface of the piezoelectric layer 113.

Although it is shown in FIG. 2A and the like that the amorphous layer 114 formed by performing surface treatment on the piezoelectric layer 113 and the piezoelectric layer 113 under the amorphous layer 114 are completely separated in an up and down relationship, the present invention is not limited thereto. For example, the amorphous layer 114 modified by surface treatment and the original piezoelectric layer 113 may be mixedly arranged on the top surface of the piezoelectric substrate 110, and in another embodiment, the amorphous layer 114 may be formed under the surface of the piezoelectric layer 113.

A plurality of IDT electrodes 150 may be arranged on the piezoelectric substrate 110, and although it is shown in FIG. 2A that five IDT electrodes 150 are formed on the piezoelectric substrate 110 as an example, this is a simplified structure for explanation, and it goes without saying that five or more IDT electrodes 150 constituting the SAW resonator 100 may be arranged.

The IDT electrodes 150 may correspond to a plurality of electrodes alternately extending from two busbars facing each other on the surface of the piezoelectric substrate 110. Velocity of the surface wave of the SAW resonator 100 may be determined by the pitch, which is the distance between IDT electrodes 150 neighboring to each other.

The IDT electrode 150 may be formed by sequentially stacking the seed layer 120 and the main electrode layer 130.

For example, the seed layer 120 may be made of one of materials having a hexagonal close-packed crystal structure, such as titanium (Ti), magnesium (Mg), zinc (Zn), cadmium (Cd), scandium (Sc), and ruthenium (Ru), or configured as an alloy or a stacking structure made of two or more selected from the above materials. Preferably, it may include titanium having the smallest diffusion coefficient, as much as 0.3×10⁻⁶ cm²/s, among the materials described above. Through this, the seed layer 120 may function as a barrier layer for preventing diffusion into the piezoelectric substrate 110 when the main electrode layer 130 is formed.

In some embodiments of the present invention, the seed layer 120 may be formed to be smaller than or equal to 10 nm. When the seed layer 120 is thicker than this, since resistance of the material such as titanium or the like constituting the seed layer 120 is high, it may have a negative effect on the performance of the SAW resonator 100.

The main electrode layer 130 may be formed on the seed layer 120. The main electrode layer 130 may include at least any one material among materials having high conductivity such as copper (Cu), silver (Ag), gold (Au), platinum (Pt), and tungsten (W) or an alloy using any one of the materials as a main material.

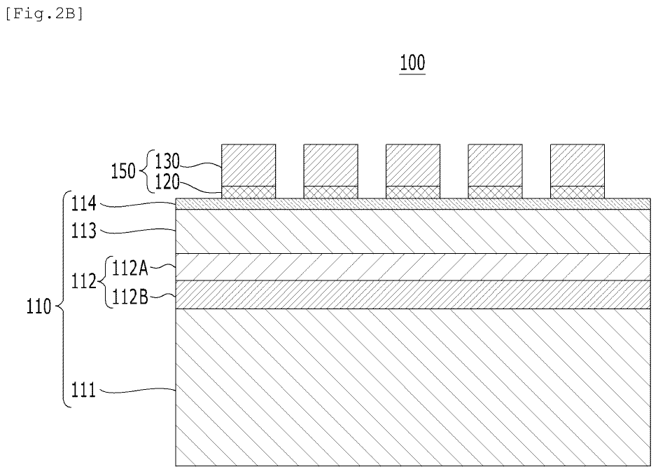

As the main electrode layer 130 forms a lattice alignment structure by the seed layer 120, crystallinity and orientation may be improved when the main electrode layer 130 is formed. This will be described in more detail with reference to FIG. 3.

FIG. 3 is a view for explaining the effect of a SAW resonator according to an embodiment of the present invention.

Referring to FIG. 3, LiTaO₃ (LT) included in the piezoelectric layer 113 and aluminum forming the main electrode layer 130 have lattice structures different from each other. Particularly, since the aluminum inherently has a cubic structure, it is difficult to form an aligned structure with LT or LN forming the piezoelectric layer 113. Therefore, as described above, the crystallinity and orientation of the main electrode layer 130 may be lowered, and etching quality of the main electrode layer 130 may also be lowered.

However, orientation and crystallinity of the SAW resonator 100 according to an embodiment of the present invention can be improved through lattice alignment of the main electrode layer 130 formed by the seed layer 120 formed between the piezoelectric layer 113 and the main electrode layer 130.

The degree of miniaturization of the SAW resonator 100 of the present invention has a correlation with the thickness of the main electrode layer 130. That is, as the thickness of the main electrode layer 130 increases, miniaturization can be achieved through reduction of the acoustic velocity of the surface acoustic wave generated by the IDT electrode 150 and reduction of the pitch of the IDT electrodes 150. However, as increase in the thickness of the main electrode layer 130 has been limited due to the etching quality of the main electrode layer 130 described above, miniaturization of the SAW resonator 100 can be further improved by the stacking structure of the IDT electrode 150 included in the SAW resonator 100 of the present invention.

In addition, as the piezoelectric layer 113 includes the amorphous layer 114 formed on the surface through ion implantation or plasma treatment, the deposition and etching characteristics of the IDT electrode 150 can be improved by minimizing the effect of the lattice structure and angular characteristics unique to the piezoelectric substrate 110, especially, the piezoelectric layer 113.

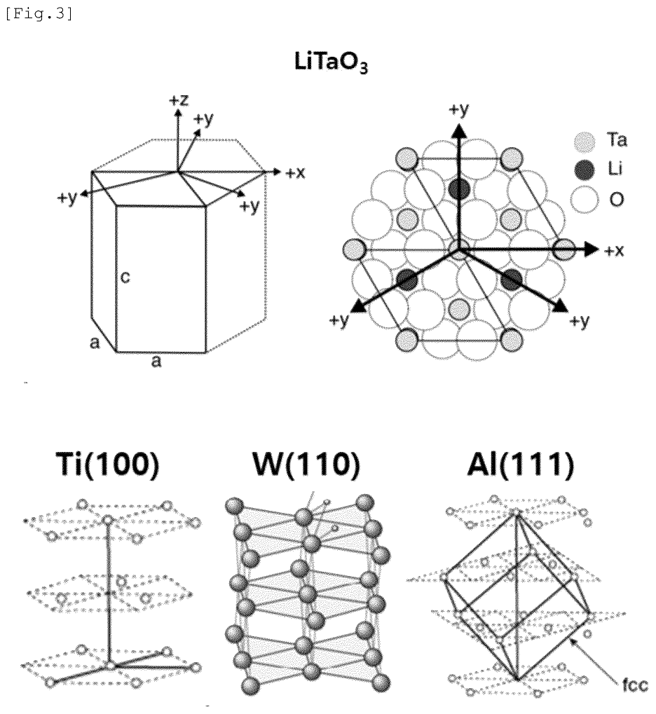

Referring to FIG. 4A, graphs of the crystallinity of the main electrode layer 130 in the case of inserting Ti as the seed layer 120 (LT/Ti/W/Al graph) and in the case of not inserting Ti (LT/W/Al) are shown. This is a case where tungsten and aluminum are included as the main electrode layer 130, respectively, in which the horizontal axis is 2 Theta, and the vertical axis represents intensity, and it can be seen that the graphs show high crystallinity of the main electrode layer 130 since the peak value is much higher when the seed layer 120 is inserted.

On the other hand, referring to FIG. 4B, graphs of the orientation of the main electrode layer 130 in the case of inserting Ti as the seed layer 120 (LT/Ti/W/Al graph) and in the case of not inserting Ti (LT/W/Al) are shown. FIG. 4B shows XRD intensity of aluminum, which is the main electrode layer 130, in the direction of 111. Like the crystallinity described above, seeing only the peak value of the XRD intensity when the seed layer 120 is inserted, it can be confirmed that the graphs show improved orientation of the main electrode layer 130.

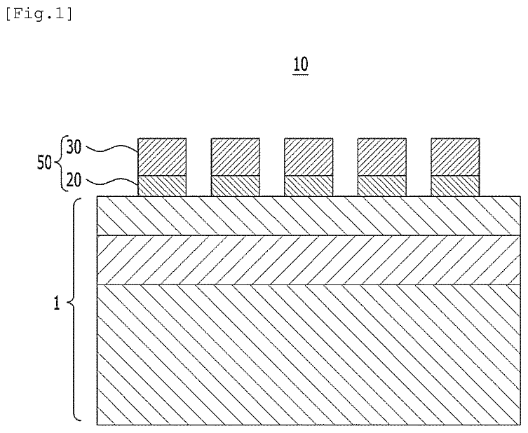

Referring to FIG. 4C, graphs showing the attenuation characteristics of the SAW resonator having an IDT electrode of the present invention in the low band is shown. The graph on the left is an enlarged portion of the passing band in the graph on the right. In the case of a red line corresponding to a structure in which the first metal layer 20 and the second metal layer 30 are stacked on the substrate 1 in sequence, as shown in FIG. 1, unwanted spurious appears as a large amount of ripple compared to the reference of the black line. In the left graph, the black line is a reference in which only the main electrode layer 130 is formed without the seed layer 120.

On the other hand, in the case of blue (and green) lines corresponding to the stacked structure of the seed layer 120 and the main electrode layer 130 like the SAW resonator 100 of the present invention, it can be seen that the performance is equal or higher, such as a decrease in loss compared to the reference.

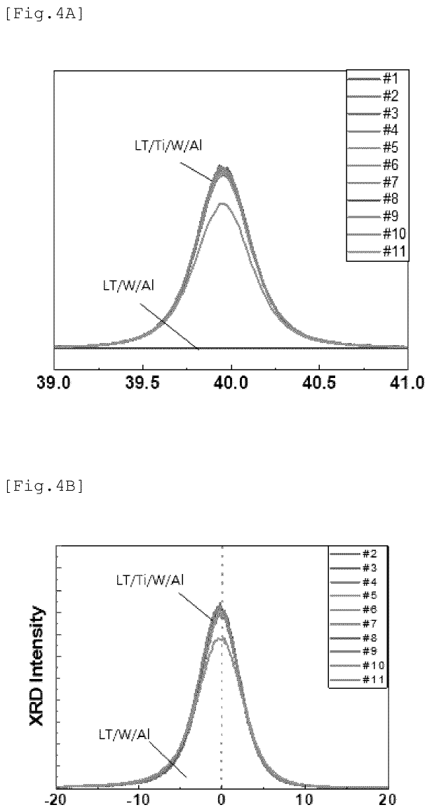

FIG. 5 is a view showing a SAW resonator 200 having an improved electrode structure according to another embodiment of the present invention. Components having reference numerals similar to those of the previously described embodiments may be understood as components corresponding thereto, respectively, and detailed description thereof will be omitted.

Referring to FIG. 5, the main electrode layer 230 of a SAW resonator 200 according to another embodiment of the present invention may be divided into a lower main electrode layer 231 and an upper main electrode layer 232.

The SAW resonator 200 in this embodiment may include a main electrode layer 230 structure divided into a lower main electrode layer 231 including a material having a density higher than that of an upper main electrode layer 232 in order to reduce velocity of the surface acoustic wave transferred by the IDT electrode 250.

The lower main electrode layer 231 may include a material having a density higher than that of the metal material constituting the upper main electrode layer 232, such as tungsten (W). For example, each of the lower main electrode layer 231 and the upper main electrode layer 232 may include tungsten (W) and aluminum (Al), which are easy to form a hexagonal close-packed crystal structure.

In this way, acoustic velocity of the surface acoustic wave can be reduced by the structure of the main electrode layer 230 in which the second metal layer 232 of low density is stacked on the lower main electrode layer 231 of high density, and this may contribute to miniaturization of the SAW filter 200.

In addition, as shown in FIG. 5, when the lower main electrode layer 231 and the upper main electrode layer 232 are made of tungsten and aluminum, respectively, each of the tungsten and the aluminum has a lattice structure different from that of the LT or LN included in the piezoelectric layer 213, i.e., a cubic structure, and thus it is difficult to form an aligned structure. However, owing to the presence of the seed layer 220, the orientation and crystallinity of the SAW resonator 200 of the present invention can be improved through lattice alignment of the metal layers forming the lower main electrode layer and the upper main electrode layer 231 and 232.

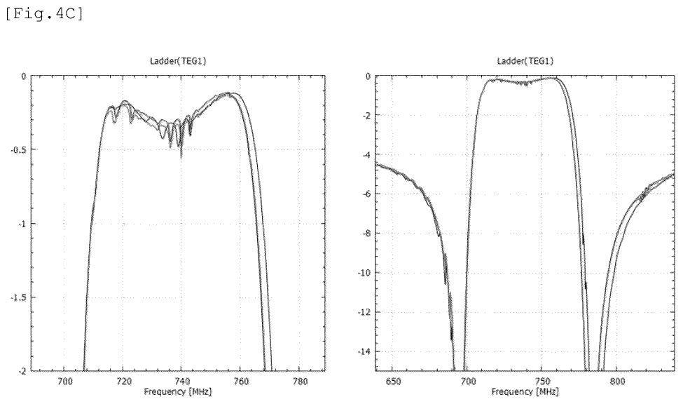

FIG. 6 is a view showing a SAW resonator 300 having an improved electrode structure according to another embodiment of the present invention.

Referring to FIG. 6, in the SAW resonator 300 according to another embodiment of the present invention, an insulating layer 360 may be interposed between an IDT electrode 350 and a piezoelectric substrate 310, more specifically, between a seed layer 320 and an amorphous layer 314. The insulating layer 360 may include, for example, silicon oxide (SiO₂), silicon nitride (SiNx), or the like.

The insulating layer 360 is formed between a piezoelectric layer 313 and the IDT electrode 350 to further improve the etching quality of the IDT electrode 350 without deteriorating the orientation and crystallinity of the main electrode layer 330.

Since the bandwidth of the SAW resonator 300 can be reduced when the insulating layer 360 is too thick, a thickness of the insulating layer 360 not to affect the bandwidth of the SAW resonator 300 is preferable.

Meanwhile, although the insulating layer 360 formed between the IDT electrode 350 and the piezoelectric substrate 310 may be formed in the shape as shown in FIG. 6, the present invention is not limited thereto. The insulating layer 360 may be formed only directly under the seed layer 320, and as the insulating layer 360 between neighboring IDT electrodes is removed, the insulating layers 360 under the neighboring IDT electrodes 350 may be arranged to be separate from each other.

In addition, the IDT electrode 350 may be formed in a dual structure of the lower main electrode layer 231 and the upper main electrode layer 232 shown in FIG. 5.

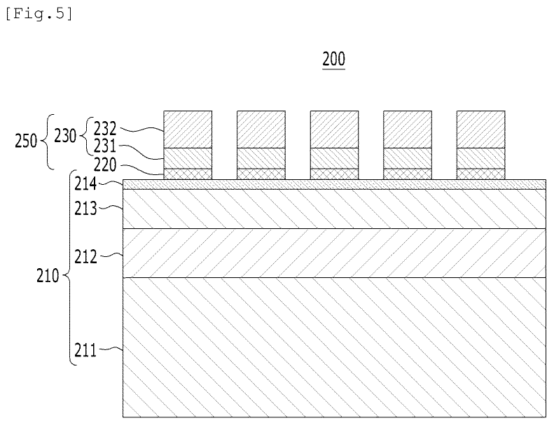

FIG. 7 is a view showing a SAW resonator having an improved electrode structure according to still another embodiment of the present invention. As described above, components having reference numerals similar to those of the embodiments described with reference to FIGS. 2A and 5 may be understood as components corresponding thereto, respectively, and detailed description thereof will be omitted.

Referring to FIG. 7, at least one of the IDT electrodes 450 of the SAW resonator 400 having an improved electrode structure according to another embodiment of the present invention may be a contact electrode on which a wiring layer 480 is formed.

The IDT electrode 450 may further include an ohmic contact layer 470 formed on the main electrode layer 430. The ohmic contact layer 470 may prevent oxidation of the main electrode layer 430 and reduce contact loss with respect to the wiring layer 480 formed on the IDT electrode 450.

Specifically, the ohmic contact layer 470 may include a material having a low diffusion coefficient or a low ionization tendency, such as titanium, silver, gold, or platinum, and in some embodiments, the ohmic contact layer 470 may include a material the same as that of the seed layer 420 and the lower wiring layer 481. Preferably, titanium relatively inexpensive and having a sufficient tunneling effect may be included in the ohmic contact layer 470.

When the main electrode layer 430 including aluminum or the like is exposed on the top of the IDT electrode 450, an oxide (for example, aluminum oxide (Al₂O₃)) of the main electrode layer 430 is naturally generated, and this may increase the contact loss and lower the performance as a capacitive contact is formed rather than an ohmic contact when the main electrode layer 430 is in contact with the wiring layer 480.

Accordingly, the SAW resonator 400 according to this embodiment forms the ohmic contact layer 470 on the top of the IDT electrode 450 to reduce the contact loss with the wiring layer 480. That is, the ohmic contact layer 470 is made of, for example, titanium the same as that of the lower wiring layer 481, and the titanium oxide in the ohmic contact layer 470, which is formed as the titanium is naturally oxidized, may minimize contact resistance when it is in contact with the lower wiring layer 481 including titanium, and prevent degradation of performance caused by the contact loss. This is due to minimization of the contact resistance as the oxygen is diffused from the titanium oxide of the ohmic contact layer 470 into the lower wiring layer 481.

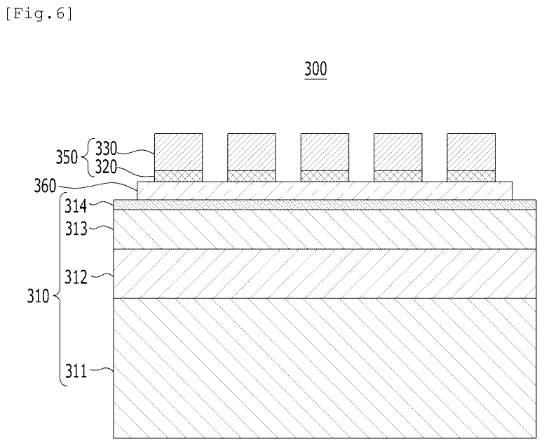

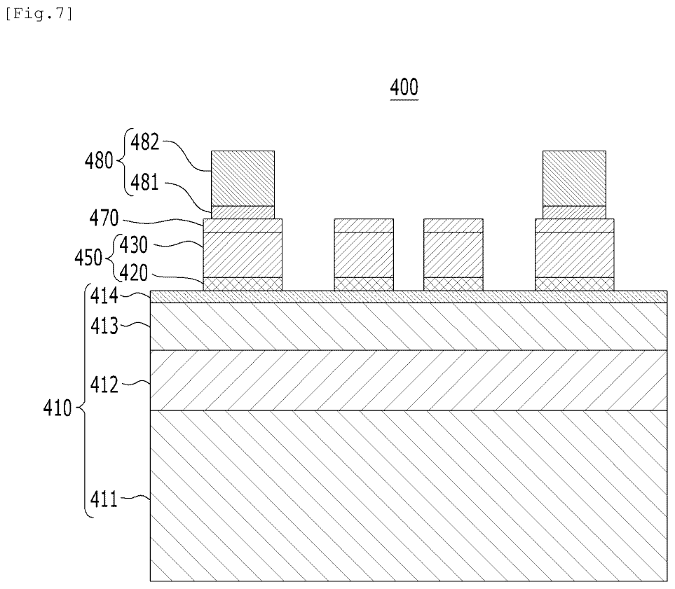

FIGS. 8 and 9 are views for explaining the effect of the SAW resonator 400 according to the embodiment of FIG. 7.

Referring to FIG. 8, as shown in the embodiment of FIG. 7, a result of forming an ohmic contact and a capacitive contact are separately shown according to the presence or absence of a contact metal layer (indicated as TiO₂ in FIG. 8).

Referring to FIG. 9, graphs comparing attenuation in the pass band when a contact metal layer 470 is formed (green graph) and attenuation when the contact metal layer 370 is not formed (blue graph) are shown. It can be confirmed that when the contact metal layer 470 is formed, there is an effect of reducing the loss as much as about 0.2 to 0.4 dB compared to the case where the contact metal layer 470 is not formed.

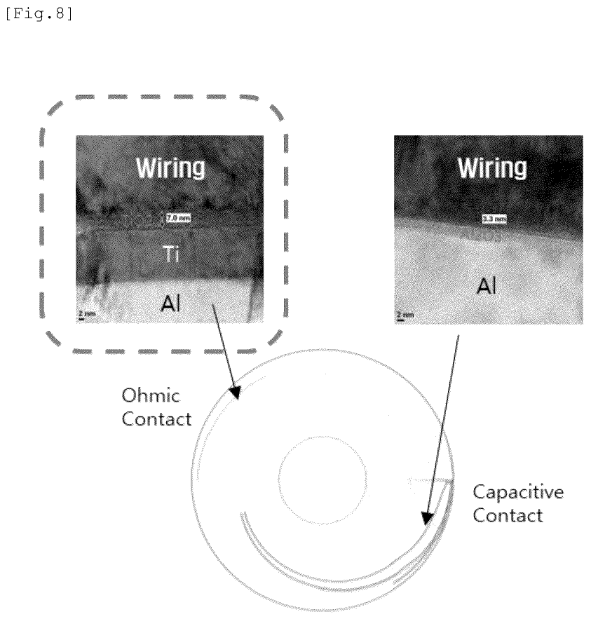

FIG. 10 is a flowchart illustrating a method of manufacturing a SAW resonator having an improved electrode structure according to an embodiment of the present invention.

Referring to FIG. 10, the method of manufacturing a SAW resonator having an improved electrode structure according to an embodiment of the present invention may include the steps of preparing a piezoelectric substrate (S110), performing surface treatment on the surface of the substrate by ion implantation or plasma treatment (S120), forming an IDT electrode film including a seed layer and a main electrode layer (S130), and forming IDT electrodes by etching the IDT electrode film (S140).

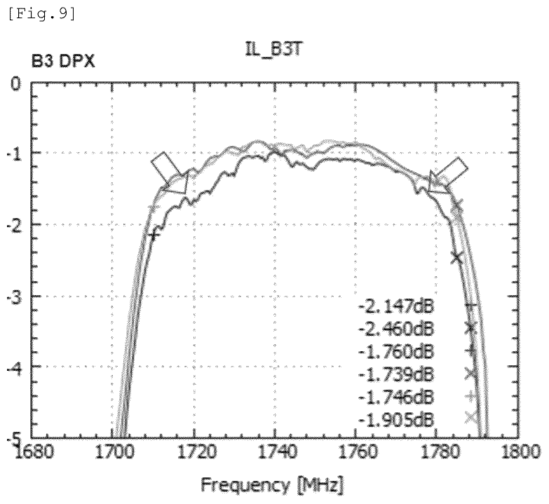

FIGS. 11 to 16 are intermediate views for explaining a method of manufacturing a SAW resonator having an improved electrode structure according to an embodiment of the present invention.

Referring to FIG. 11, a piezoelectric substrate 110 in which a support substrate 111, an energy confinement layer 112, and a piezoelectric layer 113 are sequentially stacked is provided (S110). The piezoelectric substrate 110 may be formed, for example, by bonding two or more wafers including at least some of the support substrate 111, the energy confinement layer 112, and the piezoelectric layer 113, but the present invention is not limited thereto.

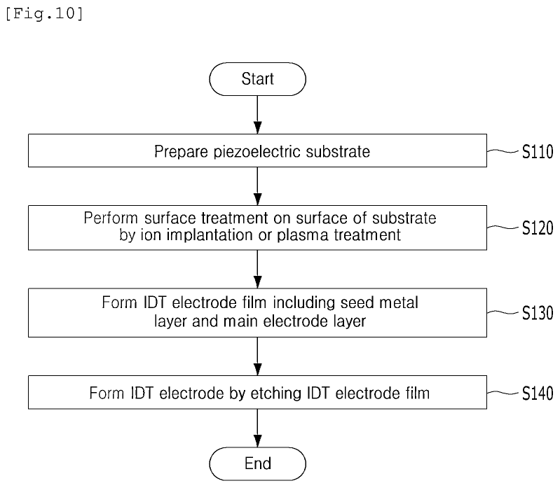

Referring to FIG. 12, a step of performing surface treatment (P) on the surface of the piezoelectric layer 113 by ion implantation or plasma treatment (S120) is performed.

For the plasma surface treatment on the piezoelectric layer 113, plasma using at least any one among, for example, argon (Ar), oxygen (O₂), nitrogen (N₂), ammonia (NH₃), neon (Ne), and xenon (Xe) may be generated. Preferably, a gas that can control the depth of the amorphous layer on the surface of the piezoelectric layer 113 generated by the surface treatment so as not to be excessively large without using a solvent in an ionized gas state like argon (Ar) may be used.

Meanwhile, the surface treatment on the piezoelectric layer 113 may form an amorphous layer on the surface by implanting hydrogen or helium ions into the piezoelectric layer 113.

In some embodiments, before the surface treatment (P) step, a process of removing contaminants on the surface of the piezoelectric layer 113 may be performed through wet cleaning or the like.

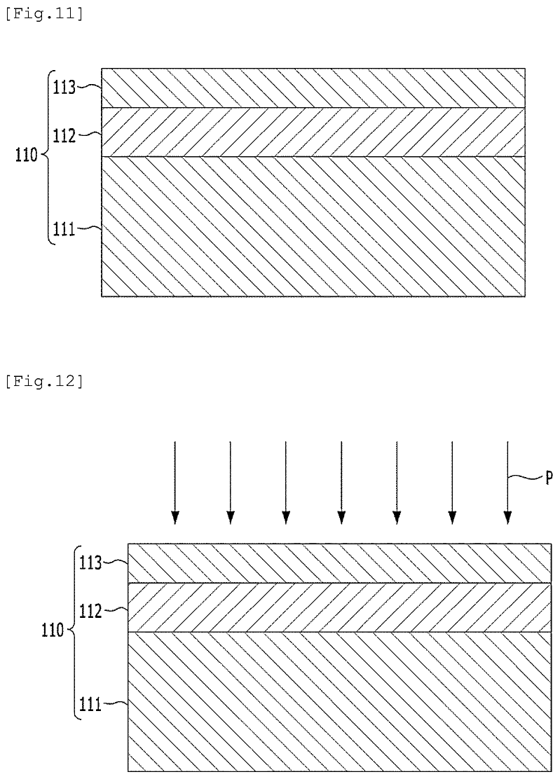

Referring to FIG. 13, a step of forming a seed layer 121 on the piezoelectric layer 113 is performed. The seed layer 121 may be produced by RF-sputtering a material such as titanium, magnesium, zinc, cadmium, scandium, ruthenium, or the like. In some embodiments of the present invention, the seed layer 121 may be formed to be equal to or smaller than 10 nm.

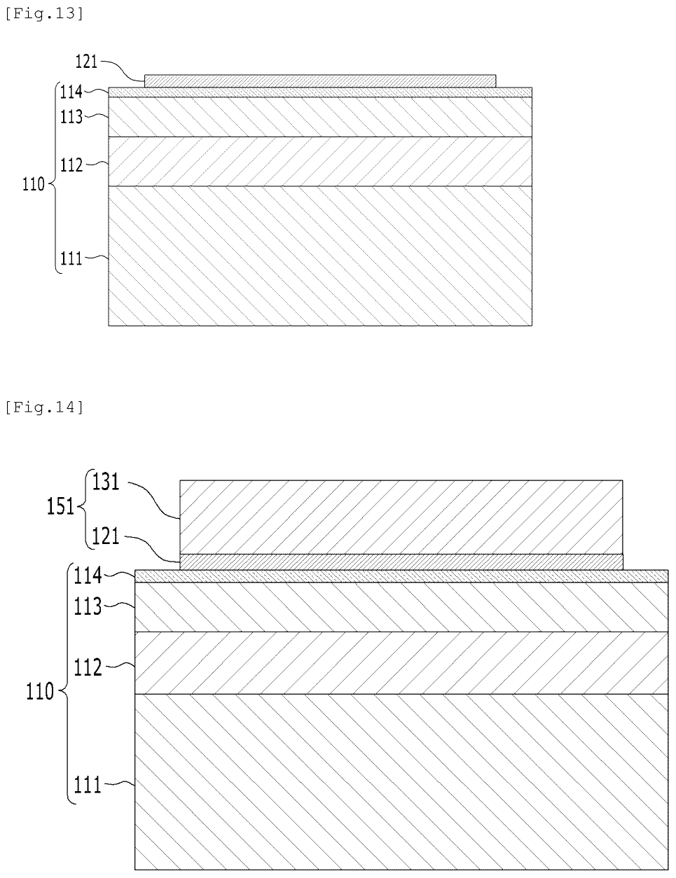

Referring to FIG. 14, a step of forming an IDT electrode film 151 by stacking a main electrode layer 131 on the seed layer 121 is performed.

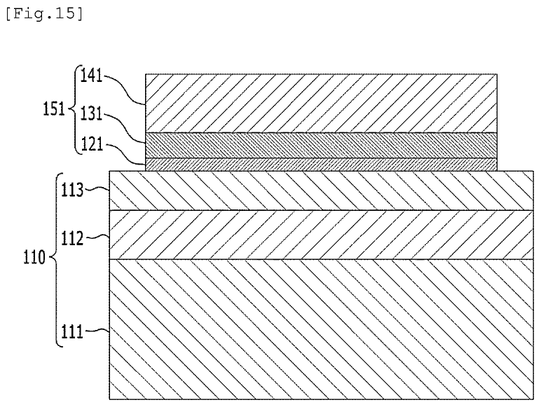

In some embodiments of the present invention, the main electrode layer may be formed to be divided into a lower main electrode layer 131 and an upper main electrode layer 141 as shown in FIG. 15. That is, this is a process of forming a structure in which the lower main electrode layer 231 and the upper main electrode layer 232 are stacked on the seed layer 220, like the SAW resonator 200 of the embodiment shown in FIG. 5. At this point, the lower main electrode layer 131 may be formed by RF-sputtering at least any one material among, for example, copper, silver, gold, platinum, and tungsten, and the upper main electrode layer 141 may be formed by RF-sputtering a material having a density lower than that of the metal material constituting the lower main electrode layer 131, such as aluminum.

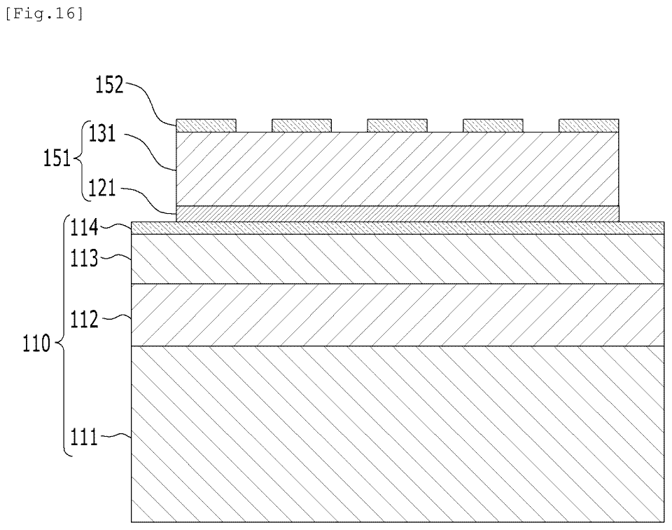

Referring to FIG. 16, a step of forming a resist pattern 152 on the main electrode layer 131 is performed. Forming the resist pattern 152 includes, for example, forming a photoresist on the main electrode layer 131 and selectively exposing part of the surface of the main electrode layer 131 by patterning through exposing and developing the formed photoresist.

Next, a step of forming the IDT electrode 150 as shown in FIG. 2A by etching the IDT electrode film 151 is performed. Forming the IDT electrode 150 may include etching the IDT electrode film 151 using the resist pattern 152 as an etching mask. Since the seed layer 121, the lower main electrode layer 131, and the upper main electrode layer 141 constituting the IDT electrode film 151 are made of different materials, their etching processes may also be performed differently, and for example, an etching process using a Cl₂ or CCl₄ gas when the seed layer 121 is titanium, an NF₃, SF₆, CF₄, or Cl₂ gas when the lower main electrode layer 131 is tungsten, and a Cl₂ or BCl₂ gas when the upper main electrode layer 141 is aluminum may be performed.

In some embodiments of the present invention, when an insulating layer is interposed under the IDT electrode, a process of etching the insulating layer using a fluorine-based gas may be added.

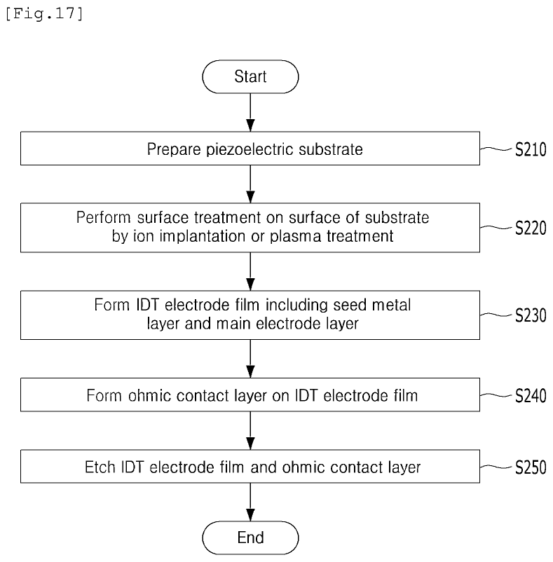

FIG. 17 is a flowchart illustrating a method of manufacturing a SAW resonator having an improved electrode structure according to another embodiment of the present invention. FIG. 17 may correspond to the method of manufacturing the SAW resonator 30 shown in the embodiment of FIG. 6.

Referring to FIG. 17, a method of manufacturing a SAW resonator according to another embodiment of the present invention includes the steps of preparing a support substrate on which an energy confinement layer and a piezoelectric layer are sequentially stacked (S210), performing surface treatment on the surface of the piezoelectric layer by ion implantation or plasma treatment (S220), forming an IDT electrode film including a seed layer and a main electrode layer (S230), forming an ohmic contact layer on the IDT electrode film (S240), and forming IDT electrodes having a contact metal layer formed on the top by etching the ohmic contact layer and the IDT electrode film (S250). Compared with the manufacturing method described above with reference to FIG. 8, there is a difference in the step of additionally forming an ohmic contact layer on the IDT electrode film, and forming IDT electrodes having a contact metal layer formed on the top by etching the contact metal layer and the IDT electrode film.

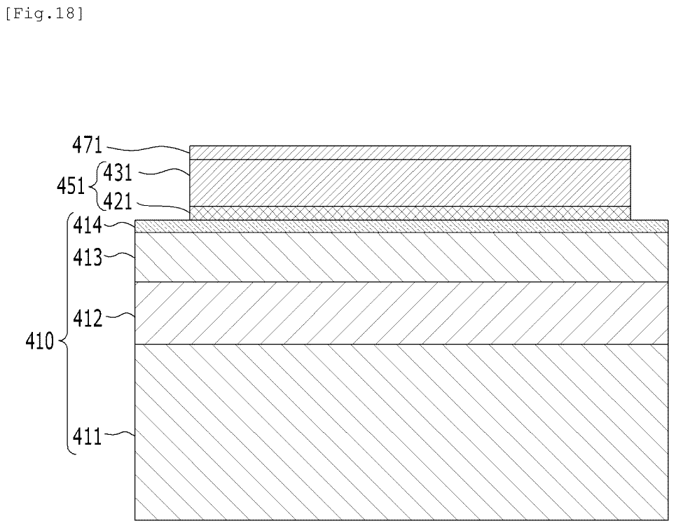

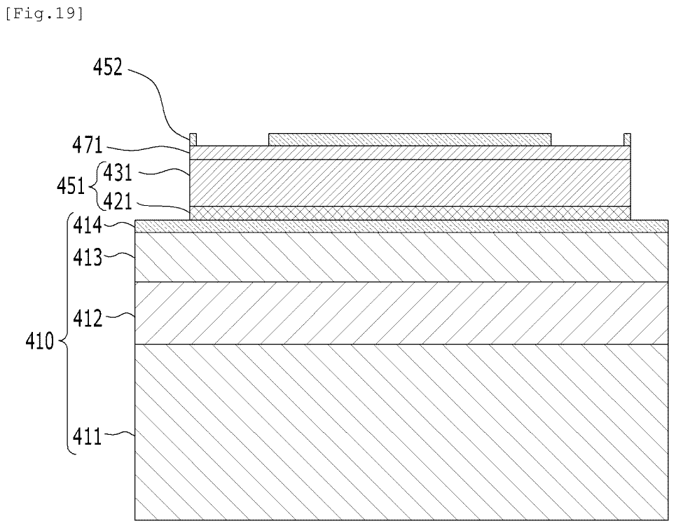

FIGS. 18 and 19 are intermediate views for explaining a method of manufacturing a SAW resonator having an improved electrode structure according to another embodiment of the present invention. Since the process up to forming the IDT electrode film 151 is the same as the process described above in the previous embodiments, description thereof will be omitted.

Referring to FIG. 18, an ohmic contact layer 471 is formed on an IDT electrode film 451 (S240). The ohmic contact layer 471 may include, for example, deposition by sputtering titanium the same as that of the lower wiring layer 481. When the lower wiring layer 481 is formed of titanium, the lower wiring layer 481 may be made of titanium oxide by natural oxidation.

Referring to FIGS. 19 and 7, a step of forming a resist pattern 452 on the ohmic contact layer 471, and etching the ohmic contact layer 471 and the IDT electrode film 451 using the resist pattern 452 as an etching mask may be performed.

Although the embodiments of the present invention have been described above with reference to the accompanying drawings, those skilled in the art may understand that the present invention can be implemented in other specific forms without changing the technical spirit or essential features. Therefore, the embodiments described above should be understood in all respects as illustrative and not restrictive.

### DESCRIPTION OF SYMBOLS

| | |
|---|---|
| 100, 200, 300, 400: SAW resonator | 110, 210, 310: Substrate |
| 111, 211, 311: Support substrate | 112, 212, 312: Energy confinement |
| | layer |
| 113, 213, 313: Piezoelectric layer | 120, 220, 320: Seed layer |
| 130, 230, 330: Main electrode layer | 150, 250, 350: IDT electrode |
| 360: Insulating layer | |
| 470: Ohmic contact layer | 480: Wiring layer |

What is claimed is:

1. A Surface Acoustic Wave (SAW) resonator having an electrode structure with improved performance, the resonator comprising:
a piezoelectric substrate; and
a plurality of IDT electrodes formed on the piezoelectric substrate, wherein
each of the plurality of IDT electrodes includes:
a seed layer stacked on a surface of the piezoelectric substrate; and
a main electrode layer formed on the seed layer, and
an amorphous layer is formed on a top surface of the piezoelectric substrate.

2. The resonator according to claim 1, wherein at least one among the plurality of IDT electrodes is a contact electrode, wherein the contact electrode further includes an ohmic contact layer formed on the main electrode layer.

3. The resonator according to claim 2, further comprising a wiring layer formed on the ohmic contact layer, being in contact with the contact electrode, and including a lower wiring layer, wherein the ohmic contact layer and the lower wiring layer form an ohmic contact.

4. The resonator according to claim 1, wherein the ohmic contact layer includes titanium, titanium nitride (TiN), titanium oxide (TiOx), and titanium-tungsten (TiW).

5. The resonator according to claim 1, wherein the main electrode layer includes a lower main electrode layer and an upper main electrode layer that are sequentially stacked.

6. The resonator according to claim 5, wherein the lower main electrode layer includes a metal having a density higher than that of the upper main electrode layer.

7. The resonator according to claim 6, wherein the lower main electrode layer includes at least any one among tungsten (W) and copper (Cu), and the upper main electrode layer includes aluminum (Al).

8. The resonator according to claim 1, wherein the piezoelectric substrate includes:
a support substrate;
an energy confinement layer formed on the support substrate; and
a piezoelectric layer formed on the energy confinement layer, wherein
the energy confinement layer includes a low acoustic velocity layer and/or a high acoustic velocity layer.

9. The resonator according to claim 1, wherein the seed layer includes at least any one among titanium, titanium nitride (TiN), titanium oxide (TiOx), titanium-tungsten (TiW), and chromium (Cr).

10. The resonator according to claim 1, further comprising an insulating layer between the plurality of IDT electrodes and the amorphous layer.

11. A method of manufacturing a SAW resonator having an improved electrode structure, the method comprising the steps of:
preparing a piezoelectric substrate;
forming an amorphous layer by performing surface treatment on a surface of the piezoelectric substrate by ion implantation or plasma treatment;
forming a seed layer on the amorphous layer;
forming a main electrode layer on the seed layer; and
forming a plurality of IDT electrodes by etching the seed layer and the main electrode layer.

12. The method according to claim 11, further comprising, before the step of forming a plurality of IDT electrodes, the step of forming an ohmic contact layer on the main electrode layer.

13. The method according to claim 12, further comprising, after the step of forming a plurality of IDT electrodes, the step of forming a wiring layer on the ohmic contact layer to be in contact with a contact electrode that is one among the plurality of IDT electrodes, wherein the ohmic contact layer and the wiring layer form an ohmic contact.

14. The method according to claim 11, further comprising, before the step of forming a plurality of IDT electrodes, the step of forming an insulating layer between the seed layer and the amorphous layer.

15. The method according to claim 11, wherein the step of forming a main electrode layer includes the step of sequentially stacking a lower main electrode layer and an upper main electrode layer, wherein
the lower main electrode layer includes a material having a density higher than that of the upper main electrode layer.

16. The method according to claim 15, wherein the lower main electrode layer includes at least any one among tungsten (W) and copper (Cu), and the upper main electrode layer includes aluminum (Al).

17. The method according to claim 12, wherein the contact metal layer includes titanium, titanium nitride (TiN), titanium oxide (TiOx), and titanium-tungsten (TiW).
